(19) United States
(12) Patent Application Publication
(10) Pub. No.: US 2003/0218927 A1
(43) Pub. Date: Nov. 27, 2003

(54) RAM memory based on nanotechnology, capable, among other things, of replacing the hard disk in computers

(76) Inventors: Yaron Mayer, Jerusalem (IL); Al J. C. Baur, Kibbutz Ramat Hashofet (IL); Haim Gadassi, Jerusalem (IL)

Correspondence Address: YARON MAYER, 21 AHAD HA'AM ST., JERUSALEM, IL

(21) Appl. No.: 10/457,388

(22) Filed: Jun. 10, 2003

Related U.S. Application Data
(63) Continuation-in-part of application No. PCT/IL01/01146, filed on Dec. 11, 2000.
(63) Continuation-in-part of application No. 10/016,968, filed on Dec. 13, 2001.

(30) Foreign Application Priority Data
Dec. 11, 2000 (IL) 140229

(51) Int. Cl. G11C 29/00

(52) U.S. Cl. 365/200

(57) ABSTRACT

As the Internet becomes faster and faster, with more and more demanding applications, and after the problems of faster routing and faster optic fibers are solved, the next main bottleneck will be the speed of the servers, and more specifically the speed (or rather the lack of it) of the hard-disks. Therefore, finding new revolutionary ways of making faster and larger hard-disks and/or larger RAM in the computer itself can help boost the computer and Internet world much faster into the future. The present invention tries to solve the problem of making much faster and much larger preferably non-volatile RAM by Using preferably 3-dimensional addressable preferably nano memory matrices instead of 2-dimensional, so that for example if instead of a 10×10 cm flat surface we have for example a 6×6×1 cm or 3×3×2 cm cube, we can get millions of Terabits, which are millions of times larger than current hard disks. So this can be used for example as computer RAM memory, as a hard-disk, or as a removable cartridge that conveniently fits in the pocket. Many variations are discussed, including memory cells that have more than two states each, and intermediate hybrid systems wherein larger preferably lithographically produced cells are each coupled to one or more nano-chips within them.

### BACKGROUND OF THE INVENTION

1. Field of the Invention

The present invention relates to RAM memory, and more specifically to a RAM memory based preferably on Nanotechnology and preferably on 3D memory instead of 2D memory, capable, among other things, of replacing the hard disk in computers, with much higher speeds and capacities compared to the current prior art hard disks.

### BACKGROUND

As the Internet becomes faster and faster, with more and more demanding applications, and after the problems of faster routing and faster optic fibers are solved, the next main bottleneck will be the speed of the servers, and more specifically the speed (or rather the lack of it) of the hard-disks. Therefore, finding new revolutionary ways of making faster and larger hard-disks and/or larger RAM in the computer itself can help boost the computer and Internet world much faster into the future.

From another point of view, the most slow and problematic elements in a computer system are its mechanical parts. As the mechanical mouse is being replaced by a much better optical mouse, and as the keyboard can be replaced by a better non-mechanical keyboard, the next main mechanical problematic part in the computer is the hard disk. So replacing it with a much faster, larger-capacity, and preferably even more reliable, medium is one of the next most important steps in the computer world.

The speeds of current prior art hard disks are around 8 milliseconds access time and theoretically up to 66 Megabytes per second transfer-time burst rate, but in practice the data transfer rate is usually less than 5 Megabytes per second. The sizes of the current prior art hard disks are around 18-170 Gigabytes. Also, because of the relatively huge seek time, caused by the mechanical nature of the hard-disk, as files become fragmented, the actual data transfer rate drops even further. All these problems would disappear with non-mechanical disks. On the other hand, the volatile RAM memory currently used in computers has a speed of about 100 nanoseconds per cell but when accessing large blocks can act as if it is about 5-12 nanoseconds, and the transfer rate is typically hundreds of times faster than the hard disk. Its size is usually around 64-512 Megabytes. The ability to make larger and faster volatile RAM is also limited by the problems of creating ever smaller circuits on silicon.

Therefore, the most promising alternatives are in the nano-world. Of these, some of the most promising are solutions based on Bucky Balls or Bucky Tubes, since they are the most readily available nano-structures that can be created today, using carbon's tendency to self-construct in such structures under the appropriate conditions. Bucky Balls (the most common one of which has 60 carbon atoms) are shaped like a football with a combination of hexagons and pentagons on the surface, with a diameter of about 1 nanometer. Bucky Tubes are similarly shaped like hollow tubes, with a diameter of typically a few nanometers for single-wall tubes and more for multi-wall tubes, typically ending at both ends with closed curves like half-balls, and a length of usually a few dozens of nano-meters up to 300 microns (usually, this size is reached when a small group of Bucky-tubes grow together side by side, so the “wire” is even stronger than if it were made of a single tube). With current technology it is possible to convert about 70% of a given amount of graphite to Bucky balls, and with a slight change about 70% can be converted to Bucky tubes instead. These balls and tubes are available today already commercially for the price of around $30 per gram, which is just about 3 times more expensive than gold, and the price will continue to drop down considerably in the next few years. Researchers are currently trying to find out why the tube growth stops at about 300 microns. The Bucky tubes and Bucky balls have some unique features that make them extremely attractive: 1. They can conduct electricity about 10-100 times better than copper, 2. They are about a 100 times stronger than steel and weigh about 4-10 times less and are much more flexible, 3. They can chemically react with a large number of elements from the periodic table, so many compounds can be created with various impurities that can lead to more interesting qualities.

There have been two attempts to plan a RAM memory based on Bucky balls or Bucky tubes: 1. HP have patented (U.S. Pat. No. 6,128,214) a 2-dimensional binary cross-bar memory based on Bucky Tubes, based on having the tubes cross each other at very small distances with some molecules at the crossing points that are oxidized or de-oxidized by electric charge, thus making the junction more or less conducting for electricity. However, their method might be problematic since the borderline conditions at the crossing points create problems of possible cross-talk from other junctions when trying to measure the conductivity of a requested junction. Their attempts to solve this are problematic and they themselves admit that this limits the number of nano-wires that can be used together. 2. Nec have patented (Published in Physics Review Letters, Vol. 82, 1999 and described in PCT application W00048195 by Tomanek et. al.) a better solution: A 2-dimensional binary memory with each memory cell based on a Bucky ball trapped within a small, slightly wider, closed Bucky tube, so that it can roll easily from one end to the other end. The ball has a tendency to stick near one of the walls due to Van der Waals forces and a weak covalent inter-wall interaction that is proportional to the contact area between the ball and the wall. This makes this memory stable and non-volatile. A short electric pulse in the appropriate direction is enough to cause the ball to move from one end of the tube to the other end in a time that is estimated to take about 4 pico-seconds, thus switching between the state of 0 to 1 or vice versa. The memory cell is read similarly by electrical means. This memory is estimated to enable a data transfer rate of about 10 TeraBytes per second, which is about a million times faster than today's hard disks. And since these structures are so small, assuming for example one memory cell per every 20 nanometers, a surface of 10×10 centimeters could contain 5 million×5 million memory cells, which is 25 Terabits, or in other words about 3 TeraBytes. Assuming that the largest hard disks today contain about 170 GigaBytes, this is about 17 times larger than the current day largest hard-disks. So in terms of speed this is quite a significant improvement, but in terms of size it is not so impressive, since normal hard-disks typically continue to double in capacity about every year. However, Nec's invention might not become practical for many years, since, although some Bucky tubes contain one or more Bucky balls spontaneously, no one has yet discovered or even suggested a way for creating neat uniform-sized Bucky tubes with one Bucky ball in each of them.

### SUMMARY OF THE INVENTION

The present invention tries to solve the problem of making much faster and much larger RAM by offering solutions that are significantly better:

The main improvements over the previous two solutions preferably include at least one of the following:

1. Using preferably 3-dimensional addressable memory matrices instead of 2-dimensional, so that for example if instead of a 10×10 cm surface we have for example a 10×10×1 cm cube, we can get, instead of 25 Terabits, for example 12.5 million Terabits, which are about 1.5 million TetaBytes, or, in other words, 8 million times larger than current hard disks. So this can be used for example as computer RAM memory, as a hard-disk, as a removable cartridge that conveniently fits in the pocket, or as a DVD or Video cartridge that can contain at the same time about 250 million movies with DVD quality. This is preferably accomplished by creating a three dimensional nano-tube wiring instead of 2 dimensional, so that at each crossing point there are 3 lines (instead of 2 lines in the other two solutions) that have to be activated in order to write data into the cell or read data from it. This is preferably designed the following way: At least one decoder is preferably used for example for the X dimension (to translate the bits of the X coordinate into the desired X line), at least one decoder is preferably used for example for the Y dimension to translate the bits of the Y coordinate into the desired Y line), but preferably each activated X or Y “line” is actually an X or Y “Wall” or vertical plane, meaning that each X line is preferably electrically connected to the corresponding X lines in preferably all the layers above and below it in the 3^{rd} dimension Z (so that activating one X line activates the entire X “wall”), and each Y line is preferably electrically connected to the corresponding Y lines in preferably all the layers above and below it in the 3^{rd} dimension Z (so that activating one Y line activates the entire Y “wall”). In addition, the desired Z is preferably activated by a Z×X or Z×Y horizontal “wall” or plane that can be activated at each layer preferably near the junctures preferably without being connected directly to the X and Y layers, and so accessing each cell is done by activating the X desired vertical “wall”, the desired Y vertical “wall”, and the desired Z horizontal “wall”. Another possible variation is that activating the Z horizontal “wall” activates the entire layer (Z×X and Z×Y), however since the Z horizontal “walls” are preferably not connected directly to the X and Y layers (except for example through AND gates, if 3 legged AND gates are used), only the desired cell that is at the juncture of the Y-Wall, X-Wall and Z-Wall will be accessed. Either way, this means that if there are for example (for simplicity of the explanation) 100×100×100 cells, there is a need for only 100 vertical connections—one for each X vertical “wall”, and 100 vertical connections—one for each Y vertical “wall”. (Of course the vertical and horizontal directions are just an example for visualization, and the whole 3d memory array can be for example rotated in any desired direction). In other words: Preferably at least 3 planes of activation are used to access each cell: an X plane, a Y plane and a Z plane, so that the intersection of these planes defines the desired cell. At each crossing point of the X-Y-Z planes, preferably there is a cell in which only activating the 3 planes can cause the desired change or read the desired state (Preferably by some physical effect that happens only when all the 3 planes are activated nor or at the cell). Another possible variation is that at each such cell there is a 3-legged AND which preferably allows connecting to the cell only if all the 3 planes intersect at that call, but that is less preferable since it means that considerably more nano-elements are needed for each cell for creating the AND gate. On the other hand, such logical AND gates might be more reliable, at least in some configurations. Another possible variation is using some sequential combination of the X-Y-Z, so that for example in order to access a cell first a certain X plane and Y plane must be activated and then for example a certain X and Z and/or Y and Z. Such a solution is preferably accompanied by cells in which only a certain sequence of steps causes the desired affect. For example if the cell is based on moving some element inside a Bucky tube, then the tube might be for example in the shape of 2 L's connected in the 3^{rd} dimension (created for example by connecting 3 Bucky tubes is the desired directions), so that only a certain sequence of movements can cause the element to move to the other end of the twisted shape. Another possible variation is to use for example a combination of 3 independent moveable nano elements in each cell so that only moving the whole 3 creates an alignment that enables for example changing or reading the cell. This is another method of creating the desired effect that only activation of the 3 dimensions will access the desired cell. An additional advantage of using 3-d cubes instead of 2-d surfaces is that it solves better the problem of induction between the neighboring wires: This induction is bigger the longer the wire and the closer the nano-wires are to each other, so having for example a 2×2×2 cm cube is better than having a 10×10 cm flat surface. Induction between the wires wastes energy and limits the switching speed, however it is relevant mainly if the same memory cell or cells are accessed again and again at very high frequencies. Also, preferably the thinnest single-cell nano-tubes are used as wires in order to reduce this problem even further, and preferably they contain Alkali metal impurities that make them even better conductors, in order to reduce this problem even further. Another advantage of having so much spare memory is that a large percent can be used for redundancy and error correction to correct for any errors that might occur for example because of quantum effects, cosmic rays, etc. One possible way that might help building such 3D structures is for example adding magnetic impurities to Bucky tubes and to Bucky balls and then using for example magnetic fields to order them in the required arrays and then creating for example alternating layers of these structures with insulating layers, preferably by combination for example with methods of masks and multi-layer lithography and/or other methods of deposition. Such masks can be used also for example for adding the needed vertical Bucky tubes between the layers, preferably in combination with magnetic field lines. However, adding the vertical connections can be easy because, since only one vertical connection is needed for each X “wall and each Y “wall”, it is possible to make these connections at the edges of the horizontal layers, so no vertical connections have to be inside the 3d cube. Another possible variation is to use for example a large number of preferably very thin two dimensional nano-memory layers stacked upon each other on the same chip, so that different layers are accessed for example by multiplexors on the outside connectors, but that could make it more expensive and require multiplexors with a very large number of connectors. In other words: Creating for example just multiple layers of 2-D memory that are not connected and are for example separated by insolating layers, preferably by depositing more and more layers on top of each other without having to deal with vertical connecting lines, but that means that each layer must have at least one X decoder and at least one Y decoder of its own, so all together much more decoders are needed in this variation, and also at least one general multiplexor or decoder is needed for choosing the desired layer. However, this configuration has the advantage that multiple cells can be accessed at different layers simultaneously. On the other hand, this is not important, since anyway preferably multiple cells are accessed simultaneously at each read or write, or even for example an entire layer each time. However if AND gates are needed at each cell, this might change the efficiency calculations: if we take an example of 100×100×100 memory cells then if creating a 3 legged AND instead of a 2 legged AND might require adding for example another 6 elements to each of the 1 million cells, which is 6 million elements, then this addition is problematic: Assuming that the decoder for a 100 “X” lines has about 1,000 logical gates and therefore about 6,000 elements, and we have just one decoder for X that activates an X vertical plane throughout all the layers and a similar decoder for the Y, and a similar decoder for the horizontal Z planes, then we have altogether 18,000 elements for the 3 decoders. On the other hand, if we use a separate X decoder and a separate Y decoder for each layer and the Z just chooses the layer, then we can use just 2 legged AND gates at the cells and thus we save 6 million elements. Because we need in this configuration a hundred times more X and Y decoders, we will need 1.2 million elements instead of 12,000 elements for the X and Y decoders, plus 6,000 elements for the Z decoder, plus AND gates to connect between the Z layer selector to the 100 X lines and the 100 Y lines at each layer, which means 200 AND gates per layer x 100 layers, which is 20,000 AND gates and therefore for example 120,000 elements. So we need altogether about 1.32 million elements for the decoders but that is still much less than the 6 million elements that are needed for adding a 3^{rd} AND leg to each cell in this example. However, the estimate might vary considerably depending on the exact technology used, since assuming for example that CMOS technology is used for the AND gates, the 3^{rd} leg of the AND can be added with just one element (a diode) instead of 6, and therefore it becomes more preferable to use the variation of using the intersection of the 3 planes and saving on the number of decoders. So if for example we just use more conventional types of memory such as SRAM or DRAM or MRAM (Magnetic RAM) but in a 3D implementation and we use CMOS AND gates, which is the type typically used in such memories, then the variation of the 3 planes intersection is more preferable. And anyway, if we use for example one of the hybrid solutions described below, where for example we use a 3D cube of larger size memory cells but within each cell is a nano-chip that can have for example another internal 1000 nano cells, then the nano-chip itself can preferably sense if 3 lines are activated next to it or just 2 and then the configuration of intersecting 3 planes and saving decoders is more attractive anyway. Similarly, if we use for example 3D memory in which some physical effect is automatically triggered only if the 3 lines are activated so no actual AND gates are needed at each cell (for example by some cumulative threshold), then the configuration of intersecting 3 cells becomes clearly more attractive. According to the above considerations, if we use for example a 3D memory based on moving an element within a Bucky ball and an AND gate is needed near each cell then preferably Bucky tubes are used for implementing a CMOS-like AND gate, so that the addition for adding the 3^{rd} leg is minimal. Another possible variation is using for example a nano-mechanical implementation of the AND gates: Since imitating a CMOS-like AND gate by Nanotechnology might require for example using a few dozen preferably small semiconductor Bucky tubes and/or Bucky balls and/or other nano elements, it might be easier for example to use just a few nano-elements which have to be for example aligned through both the X, Y and Z in order to allow for example a current to pass. Another possible variation is using for example just an AND gate with two legs at each cell and relying on the physical effect to work only if the 3^{rd} line is also activated. As explained above, Another possible variation is to create for example by similar methods 3-dimensional Magnetic RAM (like IBM's MRAM) or for example normal Dynamic RAM or static RAM, so that the memory structure is based on normal lithography and/or other known methods of deposition, but in 3-d cubes. In these cases the connections between the layers, again, can be by any of the above discussed configurations, but preferably the distances between layers are large enough so that the cells do not affect each other too much between layers. If the access to the cells in based on the intersection of 3 planes, as explained above, then preferably after the laying of layers on top of each other is finished, the vertical connections between the lines of each X plane and each Y plane are made on the external walls of the 3d cube. Preferably these vertical external connectors can be used for example also for removing heat from the 3D cube, for example by coupling them to a heat sink, preferably through an element that transfers heat well but is electrically insulating. Another possible variation is to add for example between each two layers (or at least for example between each group of layers) a preferably electrically insulated heat conducting layer, for example made of a preferably very thin plate of metal. In order to solve yield problems in creating such memory chips with a large number of layers, preferably damaged or problematic layers can be automatically diagnosed and then for example deactivated completely or in part, for example by ignoring the entire layer or for example a row or a column in it. Preferably each cell in the 3-d memory is either binary, or can assume more, preferably discrete, states. Another possible variation is using for example Bucky balls that have been treated by the new discovery of Makarova el. al., published on Nature magazine on Oct. 18, 2001, that heating and compressing the balls can force them to join together in layers like sheets or bubble wrap which then display magnetic behavior at room temperature even without adding magnetic impurities. This material is also transparent and photo-responsive and has the ability to change magnetic properties when exposed to light. (A similar process might work also for Bucky tubes). So this might be used for example to create 3d cubes of Bucky elements (balls and/or tubes) which can be written and read for example by crossing 2 or more laser beams. Another possible variation is that, in order to save movement, preferably more lasers can be switched on and off and/or preferably elongated lasers are used that cover larger planes so that less movement is needed to create intersections (for example one or more movable and/or rotateable elongated laser can move to light the desired X plane, one or more movable and/or rotateable elongated laser can move to light the desired Y plane, and one or more movable and/or rotateable elongated laser can move to light the desired Z plane), and/or the cube can be for example round like a multi-layer CD and rotate. On the other hand, this might have the disadvantage that since so many elements are joined together in larger lumps, there is less good resolution than when discrete elements are used. Therefore, another possible variation is to arrange the cells in a more orderly and discrete fashion and preferably use a separate laser source for each plane (so that for example each X planes is covered by is own elongated laser beam that can be turned on or off, each Y plane is covered by its own elongated laser beam that can be turned on or off, and each horizontal Z plane is covered by its own elongated laser beam that can be turned on or off). Another possible variation is for example to add appropriate magnetic impurities to Bucky balls (and/or for example preferably small Bucky tubes) and then mix them for example with other Bucky balls or other nano-elements that are non-magnetic, and use for example magnetic field lines during the construction, so that for example a cube is created that contains in all directions regular layers of magnetic and non-magnetic Bucky balls. Another possible variation is to use for example just magnetically doped Bucky balls in the cube, and/or for example bucky balls with such magnetic elements inside the balls (created for example by bombarding them with such elements). Assuming that the Bucky balls remain transparent and light responsive even when doped with appropriate elements (such as for example Cobalt and/or other impurities), they can then be similarly written and read in the 3-d cube for example by crossing 2 or more preferably elongated laser beams, and this way no electrical nano-wiring is needed. Another possible variation is to use for example 2 or more X-ray lasers and read and write into 3-dimensional cubes of materials that can be easily altered by the crossing of the preferably elongated beams. This has the advantage that no special light-transparent materials are needed (since most materials are transparent for X-rays), and also higher resolutions can be used because of the shorter wavelengths, compared for example to visible light holographic memory. Of course, various combinations of the above and other variations can also be used, such as for example a combination where only some of the layers and/or parts of them are connected vertically in the 3^{rd} dimension.

2. Addressing much better the interface problem (of connecting to nano-scale devices and especially if there is a much larger number of cells), which was actually not addressed at all in the other two patents: Another advantage of using a 3-dimensional cube instead of a 2-dimensional chip is that instead of connector legs that also hold it in position (as chips are interfaced today), we can have for example small flat electrically conducting squares on each surface of the cube and then the cube can be held in position for example by something that closes around it. This makes it much cheaper to create the connectors and also they are more reliable since they cannot be bent out of position while inserting or removing the chip from its socket. This is especially important since having so much more inside the chip implies also needing more connectors on the outside. This and other interface issues are described in more details in the reference to FIG. 3. Another possible variation that solves the interface problem is using a hybrid solution wherein for example each normal memory cell contains one or more nano-chips coupled to it, as described below.

3. Using preferably memory cells capable of holding more than a binary value, so as to make a more efficient use of the space. So for example, if we have a hexa-based memory instead of binary, we get 3 times more memory in the same space. An additional advantage is that the data access and transfer speed become even larger, since accessing a given number of cells gives more data at the same time that it would take to access the same number of cells containing only binary data each. This is accomplished preferably by using a cell which can be modified to a number of, preferably discrete, states, so that the fact that a non-binary value is used does not affect the reliability of reading the data. This can be done for example in the following preferable ways:

a. Using a moving element within another element, that can take for example 1 of 6 states: Up on the X-direction, down on the X-direction, up on the Y-direction, down on the Y-direction, up on the Z-direction, and down on the Z-direction. This is very convenient with a 3-dimensional crossing point of 3 wires, so that for example passing a current or voltage down on the Y path can cause the element to move down, passing a current or voltage up on the Y path can cause the element to move up, etc. However, in this configuration since also a current or voltage between just 2 wires at the juncture might cause the movement of the internal element, preferably either an AND gate is used at each cell, or for example the voltages or currents used are small enough so that only a combination or sum of 3 activated wires can cause the change. Another possible variation is to use in this case the configuration of 2-D layers stacked upon each other with an external multiplexor for the layer, so that at each cell there is either an effect between two wires or no effect at all. One of the preferable ways of accomplishing this is using for example wires made of Bucky tubes, and at each crossing point the cell is made for example by a Bucky ball, preferably chemically fused to the tubes, and inside this Bucky ball there is a preferably small element, such as for example an ionized atom or atoms or molecule or molecules, that can respond to electric or magnetic fields and then move to the required side within the Bucky ball, and stay there by Van der Waals and/or similar forces. More details of this embodiment are shown in reference to FIG. 4.

b. Using an element, such as for example a molecule, that can change in a number of discrete states, for example by chemical change. The main disadvantage is that this might be a bit slower than the previous solution, and also might be harder to accomplish by electrical means. For example, adding 3 atoms of an Alkali metal to a Bucky ball (these atoms are typically absorbed in certain places at the Bucky ball's envelope), can make it become almost super-conducting, whereas adding 6 atoms makes it stop conducting electricity altogether, and other constellations can make it become semi-conducting. Therefore, changing for example the number of atoms absorbed in the ball's envelope, can be used for creating 3 or more discrete states of electrical conductivity. This can be done for example by adding these Alkali metals to the structure near each juncture so that for example different directions or strengths of currents can change the number of Alkali atoms absorbed in the ball. Since Bucky balls can chemically react with a large number of elements, many other variations are possible.

c. Using an element that can be given a number of different, preferably discrete, energy levels, for example, adding or deleting certain amounts of electrons, magnetization at a small number of easily discernable states, etc.

4. Using preferably a memory structure that does not have problems of cross-talk, so that the number of wires used on the same matrix in not limited by such problems. This is accomplished for example by using wires that are far enough from each other and with no borderline electrical states, and therefore no cross-talk. Unlike the solutions based on electrical borderline states at the junctions of either conducting electricity or not, preferably there are no electrical connections at the junctions, and the memory cell is preferably approached by an electric field from the nearby wires, so that only the intended cell gets a field strong enough for a change to happen. So preferably at each junction either a cell is affected or not, but no electric current can leak to other wires. This is like creating an AND gate at each junction, but without having to add an actual logical AND gate. Another possible variation is to add actual AND gates but that is less preferable since it means that much more nano-elements are need for each cell. If it's a 3-dimmensioanl array then the AND gates are preferably ternary AND gates. In order to enable the electrical insulation at the junctions, either the ball (or whatever other element is used as the cell) is preferably for example surrounded by short electrically insulating nano-tubes or by any other electrically insulating atoms or molecules (such as for example by covering the Bucky balls with condensed silicon vapors or any other means or materials), or, for example, the ball itself is made insulating, for example by stuffing it with 6 atoms of an Alkali metal, or any combination of these solutions. Other methods of creating AND gates might also be used, such as for example building them from diodes based on conducting, semi-conducting, and non-conducting nano-elements, but that would make the structure less efficient, with more elements needed for each cell. Another possible variation is to add for example a constant preferably small baseline of DC current for example at the preferable metallic heat conducting layer between each two layers of the memory, in order to further reduce undesired cross-talk by inductions or by capacitance transfer. This DC current is preferably small enough so as not to affect the cells but sufficient to catch influences between the cells. Another possible variation is for example to ground the conducting layers instead of applying the DC current. Of course, various combinations of the above and other variations can also be used.

5. Using Structures that are easier to create. Unlike the idea of using Bucky-Balls within standard-sized Bucky tubes, which could be very difficult to create systematically, for example the solution described above of a small ionized atom or molecule within a Bucky ball is much easier to achieve, since bombarding the Bucky Balls with the desired particle with sufficiently strong force can systematically manufacture the Bucky Balls with the appropriate element in each of them, and also, the Bucky balls themselves are a much more regular structure than the tubes. So using Bucky balls with a moving element within them is a better solution than using Bucky tubes with a moving Bucky ball in them, even if for example just a 2-D memory is used. If Bucky balls are used, then of course various types of Bucky ball can be used, not just the most common type of C60, including structures that are somewhat in-between a Bucky ball and a Bucky tube, however the C60 type is more preferable. Another variation is to bombard for example Bucky tubes with various atoms or molecules and thus create more easily a moving element within the Bucky tube. If more than one element enter the tube or the ball, it might still work OK. On the other hand, since the internal moving element is preferably with an electric charge and/or can be magnetically charged, this might prevent more than one element of the same charge from entering the same place. Of course, other materials and nano-structures may also be used as they become available. Another problem is how to create longer nano-tubes for the wires. Apart from trying to grow them, which is what current researches in the area are mainly trying to do, or creating nano-Velcro, which means short twisted nanotubes that are supposed to connect to each other in a chain formation, as other researchers are trying, it might be possible to chemically glue together for example short Bucky Tubes of 300 micrometer. One preferably way of doing this is to grow nano-tubes for example with Cobalt and/or other impurities, which makes them magnetizeable, and then use a magnetic field in order to control their orientation and positioning (or use for example an electrostatic field for this, or both and/or for example ultrasonic acoustic waves), and then for example use holograms or extreme UV lithography in order to create masks or wave-guides for them to align in the required shape, and then bind them together, preferably by chemical means, for example with gold atoms and/or with other carbon elements. For example a mask based on extreme UV lithography can create a channel 20 nanaometeres wide, which is just 5 times wider than a 4-nano diameter Bucky-tube. In FIG. 7 we show an example of using such a mask. Another possible variation is combining the recently developed extreme-UV lithography with the graphite vapors used in the process of creating the nano-tubes, so that the heated graphite vapors are condensed around the mask created with this lithography, so that the tubes grow specifically in the areas outlined by the mask, thus making it possible to create also huge integrated circuits based on Bucky tubes. Another variation is to align the Bucky tubes in the same direction (for example by electromagnetic fields or electrostatic charge) and condense them in a small elongated space (such as for example with the extreme UV mask or by other means), and then bombard them for example with a beam of strong energy additional Bucky tubes or bucky balls or other carbon particles or atoms or other particles, which can make them fuse together, facing the desired direction, and/or apply for example a large atmospheric or mechanical pressure on them with or without additional heating. Another possible variation is for example condensing the Graphite vapors between two or more electrodes in a strong electrical field which concentrates them in the same area, which can increase the chance of getting longer and thicker Bucky tubes. For creating even longer nano-wires, when a long mask is used, preferably it is either a very long mask, or the forming nano-wire is preferably pulled to one side in the appropriate speed for example by mechanical forces and/or magnetic and/or electric forces (for example spinning it on a wheel), so that the newly added nanotubes are always added near the end of the wire. Of course various combinations of the above and other variations can also be used. Of course, other types of nano wires, apart from Bucky tubes, may also be used as they become available.

6. In addition, we show also an intermediate embodiment (shown in FIGS. 5 and 5a) that combines the present day silicon memory cells (which are today typically each a square of 120×120 nanometers and will be later for example 20-30×20-30 by use of extreme UV lithography) with using for example a large number of Bucky balls per cell, so that much more data can be held at each cell. Another possible variation, (useful especially until longer Bucky tubes are available), is to use for example 1 or more separate 2-dimensional or 3-dimensional matrices of nano-tube wires, within each area of a current-size memory cell. In this case, preferably the inner matrix contains also the logic for accessing it from outside the cell, thus becoming a nano-chip. This variation is shown in FIG. 6.

7. In any of the above solutions, when accessing the memory cells, preferably each time a large number of cells is automatically accessed at the same time in order to increase the efficiency, so that for example at least each bit is read automatically together with an additional preferably consecutive for example 31 or 63 bits, to create the desired word size, and/or even for example an entire row or line or layer in the 3d matrix can be read or written automatically by a single access.

### BRIEF DESCRIPTION OF THE DRAWINGS

FIG. 1 is a schematic illustration of a typical structure of a Bucky ball.

FIG. 2 is a schematic illustration of the typical structures of a few types of Bucky tubes.

FIG. 3 is an illustration of a preferable way of using flat connectors on the surfaces of a 3-d chip.

FIG. 4 is an illustration of a Bucky ball containing an inner moveable element.

FIGS. 5 and 5a are illustrations of a few preferable ways of using a large group of Bucky balls in combination with current memory technology.

FIG. 6 is an illustration of a preferable way of using a 2-dimensional or 3-dimensional nano-matrix within each cell of current memory size

FIG. 7 is an illustration of a preferable example of a mask helping to create larger macro-size wires based on Bucky tubes.

FIGS. 8-8b are illustrations of a preferable example of an X-Plane, Y-Plane and Z-plane and their intersection in a 3d memory cube.

### IMPORTANT CLARIFICATION AND GLOSSARY

Throughout the patent when variations or various solutions are mentioned, it is also possible to use various combinations of these variations or of elements in them, and when combinations are used, it is also possible to use at least some elements in them separately or in other combinations. These variations are preferably in different embodiments. In other words: certain features of the invention, which are described in the context of separate embodiments, may also be provided in combination in a single embodiment. Conversely, various features of the invention, which are described in the context of a single embodiment, may also be provided separately or in any suitable sub-combination. For example, 3D memory structures can be used also with binary elements, and 2D memory structures can be used also with elements that each have more than 2 discrete states. All these drawings are just exemplary diagrams. They should not be interpreted as literal positioning, shapes, angles, or sizes of the various elements. Although the nano-structures are described with reference mainly to Bucky Balls and Bucky tubes, this invention is not limited to this kind of nano-structures, and can be used also with other types of nano-structures, in other shapes and/or other materials, as they become available.

### DETAILED DESCRIPTION OF THE PREFERRED EMBODIMENTS

All of the descriptions in this and other sections are intended to be illustrative examples and not limiting.

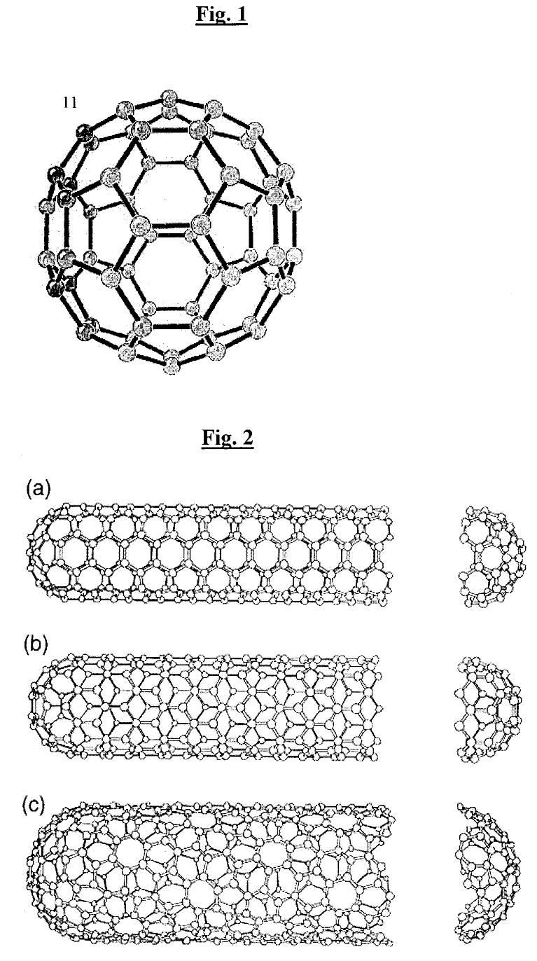

Referring to FIG. 1, we show an illustration of the structure of a C60 Bucky ball (11), made of carbon atoms with surfaces of hexagons and pentagons. The Bucky ball has a diameter of about 1 nano-meter and can trap small atoms or molecules within the inner space of the ball, however a strong force is needed to overcome atomic resistance forces for passing through between the atoms of the ball's envelope. When adding impurities to the ball, such as for example Alkali metals for even better conductivity, or Cobalt for magnetizability, they typically combine with a few specific sites on the surface of the ball.

Referring to FIG. 2, we show an illustration of the typical structures of a few types of Bucky tubes, with a cross-section of their pattern at the side. Single-wall Bucky tubes (such as tube ‘a’) are typically with a diamater of about 4 nanometers, and multi-wall tubes can be for example 20 nanometers in diameters. The length can be any length but in practice most are between a few dozens of nanometers to about 300 micron, and attempts are being made to find out why their growth typically doesn't go beyond that with the creation methods that are used today. Their electrical conductivity depends on the tube's diameter and on the chiral angle between the nanotube's axis and the zigzag direction. Tubes with straight lines of hexagons (like a) are great conductors, whereas tubes with a zigzag pattern are typically semiconductors.

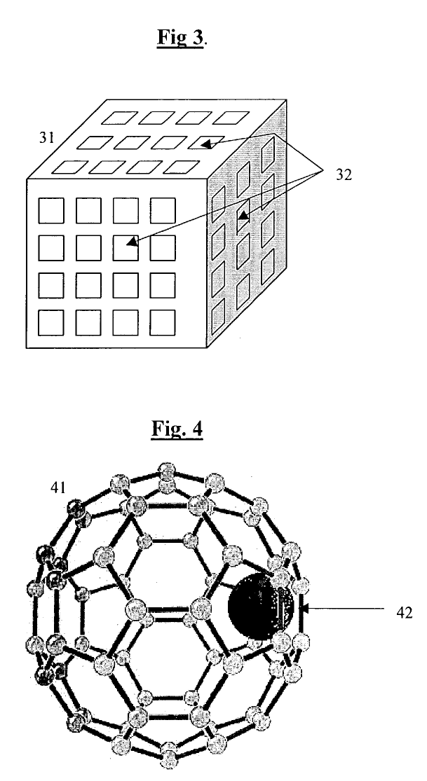

Referring to FIG. 3, we show an illustration of a preferable way of using flat connectors (32) on the surfaces of a 3-d chip (31). Instead of connector legs that also hold it in position (as chips are interfaced today), we can have for example small flat electrically conducting squares (32) on each surface of the cube and then the cube can be held in position for example by something that closes around it, such as for example an envelope with matching preferably flat connectors, divided for example into 2 or more movable parts. Preferably the closing parts contain springs on their other sides for improving the stability. In order to cool the chip the closing envelope can contain for example one or more heat sinks on one or more of the planes, or for example one or more of the external planes of the cube can be connected to one or more heat sinks instead of or in addition to the electrical connectors. If for example Bucky tubes are used in the chip, then preferably the heat sinks take advantage of their high thermal conductivity. Another possible variation is to add for example special layers of Bucky tubes and/or other good heat conductors in various places in the 3-D chip for cooling, for example as heat conducting layers between each two 2-dimensional layers or for example between each group of layers. Anyway, since typically nano-elements require little energy and since for example Bucky tubes are good heat conductors, cooling such a chip even without special additional heat conducting layers should not be much more difficult than cooling a cube of sugar. Another possible variation is to add for example a few preferably very precise small or elongated protrusions and/or sockets in a preferably small number of places and/or to make the squares or at least some of them for example also for example preferably a little sunk into the surface or preferably a little protruding, in one or more of the planes, to make sure the cube sits in place. The illustration shows only a relatively small number of squares for the sake of clarity, but in reality it can be even hundreds or more squares per cube. Of course, is can be also other shapes than squares, for example circles, elongated rectangles, etc. This makes it much cheaper to create the connectors and also they are more reliable since they cannot be bent out of position while inserting or removing the chip from its socket, as might happen for example with prior art 2-dimensional chips with a large number of connectors. This is especially important since having so much more inside the chip implies also needing more connectors on the outside. Another interface problem is that if you have for example 1 million wires×1 million wires×1 million wires in each direction, then it could require an enormous number of nano-connectors. Therefore, preferably most of the logic required for running the memory is in the chip itself, so that for example on the outside there are for example only a few hundred connectors or a few dozens or less, and the logic inside is using for example smart multiplexing to access the individual wires needed. Since Bucky tubes can be either conductors, semi-conductors or non-conductors, nano-diodes and nano-transistors can be built from them, so the entire nano-logic can be inside the RAM chip. Also, since extreme-UV lithography of for example near 20-30 nano is already beginning to become available, it can be used to create even more complex integrated circuits that will preferably interface more easily with the nanotubes within the chip, for example by using a few delta areas in which for example 4-nano wide tubes are spread a little apart from each other to interface with the (for example) 20 nano wires of the Integrated circuit. These solutions can be used also independently from other features of this invention and can be used also for other types of 3-dimensional chips—not just memory chips and not even just nano-chips.

Referring to FIG. 4, we show an illustration of a Bucky ball (41) containing an inner moveable element (42) that can take for example 1 of 6 states: Up on the X-direction, down on the X-direction, up on the Y-direction, down on the Y-direction, up on the Z-direction, and down on the Z-direction. This is very convenient with a 3-dimensional crossing point of 3 wires, so that for example passing a current down on the Y path can cause the element to move down, passing a current up on the Y path can cause the element to move up, etc. One of the preferable ways of accomplishing this is using for example wires made of Bucky tubes, and at each crossing point the cell is made for example by a Bucky ball, and inside this Bucky ball there is a preferably small element, such as for example an ionized atom or atoms or molecule or molecules, that can preferably respond to an electric charge and then move to the required side within the Bucky ball, and stay there by Van der Waals and/or similar forces. Preferably this atom (or atoms or mulecule) is for example an Alkali metal, such as for example Lithium, Sodium, or potassium, which are small and relatively easy to ionize. Also, preferably the Bucky ball's envelope is first filled up with this same element as an impurity, so that it can't absorb it anymore, so that for example if the Bucky ball can absorb a maximum of 6 Potassium atoms, then preferably it is filled up with these before the element is thrown into the ball. Also, in order to make control of the element's movements even easier, preferably the moving element, the Bucky ball, and/or at least the part of the Bucky wire closest to it, contain also some impurity such as for example Iron or Cobalt, so that they are also easily magnetizeable. However, using 6 states is just a convenient example, and other numbers of states can also be used. If, instead, a 2-dimensional memory array is used, then for example 4 discrete states could be most natural. For reading the cell, assuming for example that the Bucky ball is neutral and the molecule trapped within is charged, then either for example the resulting electrical polarity and/or the resistance of the Bucky ball is measured (non-destructive read), or for example an electric and/or magnetic field is applied near the ball destructively and then after reading the behavior, the cell is rewritten. However there can be also other configurations of something moving inside something, not necessarily in a Bucky ball, and it can even be a Bucky Ball inside a Bucky tube but preferably in a 3-dimensional array, or, for example, a Bucky ball moving within a more complex structure, such as for example a cross or for example a 2-d or 3d Z shaped or L shaped tube. Also, the moving element (or elements) is not necessarily inside another element (or elements). For example, other variations can be made in which one or more elements are moved relative to each other without being one contained in the other, or one or more element has its shape and/or orientation changed. Other variations are also possible in which the writing is irreversible, like for example in writeable CD-ROMs.

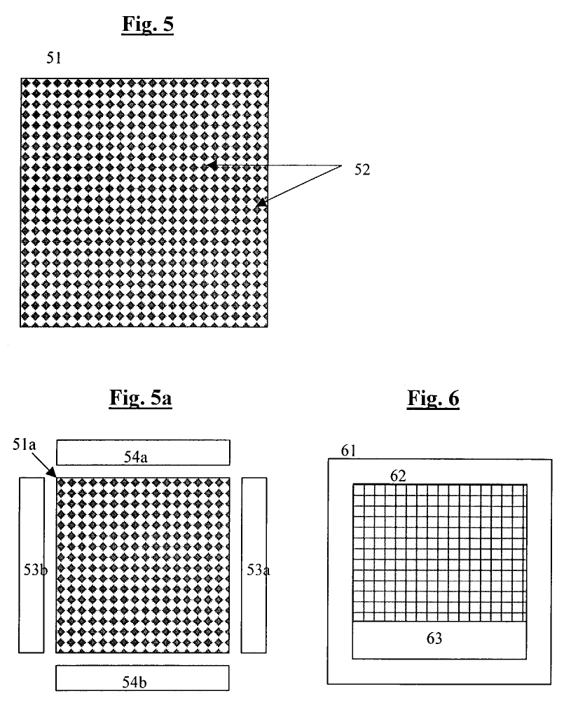

Referring to FIGS. 5 and 5a, we show an illustration of a preferable example of using a large group of Bucky balls in combination with current memory technology. This is an intermediate solution that enables using for example Bucky balls within current-sized lithographically produced silicon memory cells, so that they can be used in combination with existing methods. Each memory cell (51, 51a) contains a group of Bucky balls (52) (and/or for example Bucky tubes and/or for example other Nano-structures) which are coupled to the cell's surface for example by glue or by chemical means such as for example fluor molecules. The memory cell (51) is prefereably created by conventional lithography methods (and, as soon as extreme UV methods become more available, by extreme UV lithography), and the Bucky balls or tubes are added to the cell's surface preferably also during the lithography process, in order to be able to control where they are going (for example by a combination of electrical charge and/or magnetic fields, an appropriate mask, and chemical reactions). The balls (or tubes) can be for example more or less evenly distributed on the cell's surface, or for example more concentrated near the cell's center. They may be attached directly to the silicon surface, or an additional intermediate layer of material can be used between them and the surface. Preferably, the number of Bucky balls per square is controlled as much as possible so that this number is more or less the same in all the cells. The mass of balls (or tubes) attached to the cell's surface can then for example be magnetized (if they contain also for example some Cobalt impurity) or electrically charged to various degrees (for example 10 possible values, or 100, etc.), and then when the value is read it is determined statistically. Another variation (shown in FIG. 5a) is using some chemical or mechanical interaction with the balls, so that, for example, on the right and left side of the silicon square are small plates of one material (53a and 53b) (or other shapes) and on the other 2 opposite sides are similar plates (or other shapes) of another material (54a and 54b), so that each of the two materials has for example different electrical and/or magnetic qualities, such as, for example, copper and beryllium. In this case, preferably the values of the cell are created for example by bombarding the Bucky balls by different amounts of beryllium and copper (applied for example by passing a current in the appropriate direction, in a way somewhat similar to electrolysis). Another possible variation is for example making the Bucky balls or tubes more or less conducting by similarly changing the amount of Alkali metals absorbed by each. (If actual current is needed, then the wires have to actually touch the cell, so preferably also AND gates are used, so that, for example, all the X-wires are attached the right legs of the AND gates and all the Y-wires are attached to the left legs of the AND gates). The value of the cell can then be read for example by checking the magnetic and/or electrical charge of the group of Bucky balls, or by using an additional plate above the square which bombards the balls from above, and then the number of atoms hitting the silicon from above affect the electrical value that the silicon surface gets. Another variation is using atoms of a material of which only one atom can be absorbed in each Bucky ball, so that, for example, the number of balls that contain the material can represent discrete values of the memory cell. This can improve the reliability of deciding the exact value when reading the cell. Other variations are also possible in which the writing is irreversible, like for example in writeable CD-ROMs. Of course, various combinations of the above variations can also be used. Of course smaller or larger external memory cells can also be used.

Referring to FIG. 6, we show an illustration of a preferable way of using a 2-dimensional or 3-dimensional nano-matrix within each cell of conventional memory size, or any other convenient size (For example if the nano-chips are bigger and for example 3-dimensional, it might be more efficient to have larger external cells that each contain the larger internal nano-chip). This is somewhat similar to the embodiments described in the reference to FIGS. 5 and 5a, except that inside the normal-size memory cell, instead of a bunch of Bucky balls or Bucky tubes which are not individually addressable, the cell (61) preferably contains a two or three dimensional inner matrix (62) of nano-cells, which are preferably individually addressable through a logic unit (63). Preferably, when addressing a specific element in the inner matrix, the electric lines that reach the cell (61) carry also some data, for example through fast pulses, that tell the logic unit (63) which individual inner cell or group or range of cells it wishes to access (for example by giving it 1 or 2 or 3 coordinates of the individual inner cell, or the coordinates for a range of cells, so that for example a large group of cells can be read or written simultaneously. For example the accessing of an inner nano-chip that contains for example 1000 nano-cells, each with a binary or larger value, the nano chip might be accessed by sending each time for example first the cell number of 1 to 1000 and then the desired value, if it is access for writing, and if for example a 100 cells are accessed at the same time, then the address might be for example given as 100-199, followed by the desired 100 values). More than one nano-matrix per cell can also be used. In order to construct this, the nano-matrices, preferably including also their logic units already attached to them, are preferably first constructed separately in bulk quantities, and are then inserted into the cells for example as a cloud during the lithography process. In other words, this can be thought of as a configuration wherein each normal-size memory cell contains inside one or more small nano-RAM chips or nano-RAM arrays. This internal chip can be for example of any of the possible variations described in this invention. This inner chip's logic unit can communicate with the cell for example through an electric and/or magnetic field, and/or by other means, such as for example photons. The inner nano-cells, can be, again, either binary, or of more than 2 states. Another variation is that, for example, instead of requesting individual internal cells, the inner matrix and logic are able to store and extract an exact number varying for example from 0 to many millions (representing, for example, 32 or 64 data bits), however this is less flexible and less efficient than the previous version. Another possible variation is stacking for example multiple layers of such hybrid memory upon each other, so that in each layer each normally accessed cell is coupled to one or more nano-chips, and thus the 3^{rd} dimension is also used on the macro level. Another variation, which is some hybrid or intermediate between the version of FIG. 6 and the versions of FIGS. 5-5a, is some internal structure which can “count itself” and thus decide for example how many Bucky balls are in a certain state or create the required number in that state. This is of course much less efficient than using for example each ball as an individually addressable nano-cell, however it might be easier to build. Another possible variation is to use for the inner cells for example a 2D cross-bar nano-memory of the type described by the above HP patent or a 3D cross-bar nano-memory, since within each cell smaller memory arrays are sufficient so the problem of cross-talk is less problematic. Of course, various combinations of the above variations can also be used. Of course smaller or larger external memory cells can also be used.

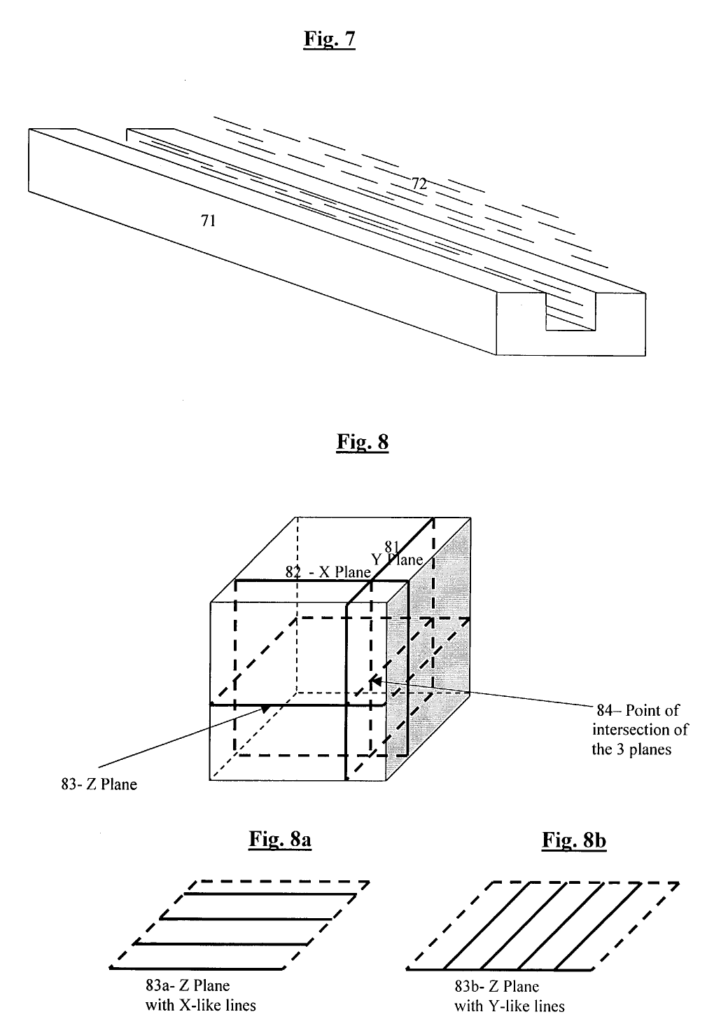

Referring to FIG. 7, we show an illustration of an example of a mask (71) helping to create larger macro-size wires based on Bucky tubes (72) that are condensed in the mask, preferably by any of the methods described above in the patent summary. For clarity of the illustration the mask is quite wide compared to the Bucky tubes shown, but in reality it can be much closer to their width, as explained in clause 5 in the patent summary. For example a mask based on extreme UV lithography can create a channel 20 nanaometeres wide, which is just 5 times wider than a 4-nano diameter Bucky-tube. One preferably way of creating longer nano-tubes is to grow nano-tubes that contain also for example Cobalt and/or other magnetic impurities, which makes them magnetizeable, and then use an electromagnetic field in order to control their orientation and positioning (or use for example an electrostatic field for this, or both and/or for example ultrasonic acoustic waves), and then for example use holograms or extreme UV lithography in order to create masks or wave-guides for them to align in the required shape, and then bind them together, preferably by chemical means, for example with gold atoms, which are good and stable electrical conductors. Another possible variation is combining the recently developed extreme-UV lithography with the graphite vapors used in the process of creating the nano-tubes, so that the heated graphite vapors are condensed around the mask created with this lithography, so that the tubes grow specifically in the areas outlined by the mask. In addition to this, adding pressure and/or heat and/or various gases to the vapors might help this even further. Another variation is to align the Bucky tubes in the same direction (for example by electromagnetic fields or electrostatic charge) and condense them in a small elongated space (such as with the extreme UV mask or by other means), and then for example bombard them with a beam of strong energy additional Bucky tubes or Bucky balls or other Carbon particles or carbon atoms or other atoms, which can make them fuse together, facing the desired direction, and/or apply for example a large atmospheric or mechanical pressure on them with or without additional heating, and/or use for example mathane gas with heat or microwave radiation on them, which can create thin diamond coatings and might help the Bucky tubes fuse this way. Another possible variation is for example condensing the Graphite vapors between two or more electrodes in a strong electrical field which concentrates them in the same area, which can increase the chance of getting longer and thicker Bucky tubes. For creating even longer nano-wires, when a long mask is used, preferably it is either a very long mask, or the forming nano-wire is preferably pulled to one side in the appropriate speed for example by mechanical forces and/or magnetic and/or electric forces (for example spinning it on a wheel), so that the newly added nanotubes are preferably added near the end of the wire. Of course, many such elongated masks can be used for example side by side, in order to create many bucky wires at the same time. Another possible variation is to use any of the above variations for example in combination with vacuum deposition and/or electro-deposition. Of course various combinations of the above and other variations can also be used.

Referring to FIG. 8, we show an illustration of a preferable example of an X-Plane (82), Y-Plane (81) and Z-plane (83) and their point of intersection (84) in a 3D memory cube in which the layers are partially connected vertically in order to save decoders. As explained in clause 1 of the patent summary, preferably at least one decoder is preferably used for example for the X dimension (to translate the bits of the X coordinate into the desired X line), at least one decoder is preferably used for example for the Y dimension to translate the bits of the Y coordinate into the desired Y line), but preferably each activated X or Y “line” is actually an X or Y “Wall” or vertical plane, meaning that each X line is preferably electrically connected to the corresponding X lines in preferably all the layers above and below it in the 3^{rd} dimension Z (so that activating one X line preferably activates the entire X “wall” (82)), and each Y line is preferably electrically connected to the corresponding Y lines in preferably all the layers above and below it in the 3^{rd} dimension Z (so that activating one Y line preferably activates the entire Y “wall” (81)). In addition, the desired Z is preferably activated by a Z×X or Z×Y horizontal “wall” or plane that can be activated at each layer preferably near the junctures preferably without being connected directly to the X and Y layers. In other words, a Z×X horizontal plane can look like a comb (83a) with rods in the X direction, as shown in FIG. 8a and a Z×Y horizontal plane can look like a comb with rods in the Y direction (83b), as shown in FIG. 8b. And so accessing each cell is preferably done by activating the X desired vertical “wall”, the desired Y vertical “wall”, and the desired Z horizontal “wall” (83), which activates for example horizontal Y lines at that horizontal layer or horizontal X lines at that horizontal layer. Another possible variation is that activating the Z horizontal “wall” activates a mesh-like layer (Z×X and Z×Y) (So this would look like a mesh instead of a comb), however since the Z horizontal “walls” are preferably not connected directly to the X and Y layers (except for example through AND gates, if 3 legged AND gates are used), only the desired cell that is at the juncture of the Y-Wall, X-Wall and Z-Wall will be accessed. However, this is not necessary, since each of the two “combs” is sufficient to reach near all the junctures of that layer. Either way, this means that if there are for example (for simplicity of the explanation) 100×100×100 cells, there is a need for only 100 vertical connections—one for each X vertical “wall”, and 100 vertical connections—one for each Y vertical “wall”. (Of course the vertical and horizontal directions are just an example for visualization, and the whole 3d memory array can be for example rotated in space in any desired direction). In other words: Preferably at least 3 planes of activation are used to access each cell: an X plane (82), a Y plane (81) and a Z plane (83), so that the intersection (84) of these planes defines the desired cell. Of course the cube does not need to have the same number of elements in each of the 3 dimensions.

While the invention has been described with respect to a limited number of embodiments, it will be appreciated that many variations, modifications, expansions and other applications of the invention may be made which are included within the scope of the present invention, as would be obvious to those skilled in the art.

We claim:

1. A 3-Dimensional Random Access Memory (RAM) system for data storage and retrieval, comprising:
A large number of memory cells, each located at the crossing of at least two wires;
Control circuits for accessing said cells;
External connectors for interface with other devices.

2. The system of claim 1 wherein at least one of the following features exist:
a. Said cells are nano-cells and at least the wires closest to the cells are nano-scale in terms of their thickness and distances from each other.
b. Said cells are normal RAM cells or MRAM (Magnetic RAM cells) but in a multi-layer structure.
c. Between at least some of the layers a heat conducting layer is used.
d. Between at least some of the layers a conducting layer is used which is grounded or carries a small constant DC current.
e. Each time a large number of cells is automatically accessed at the same time in order to increase the efficiency and/or even an entire layer in the 3d matrix can be read or written automatically by a single access.
f. Said cells and wires are in multiple layers of 2-dimensional arrays and at least 2 decoders are used in each layer for accessing the cells and there is at least one decoder or multiplexor for choosing the layer.
g. Said cells and wires are in a 3-dimensional array and at least 3 planes of activation are used to access each cell: an X plane, a Y plane, and a Z plane, so that the intersection of these planes defines the desired cell.

3. The system of claim 2 wherein said cells and wires are in a 3-dimensional array and at least one of the following features exist:
a. Said planes are defined so that Each X line is electrically connected to the corresponding X lines in the layers above and below it in the 3^{rd} dimension Z, Each Y line is electrically connected to the corresponding Y lines in the layers above and below it in the 3^{rd} dimension Z, and each Z line is connected to at least one of independent Y lines and independent X lines in the corresponding Z layer, thus creating said Z plane.
b. At each crossing point of the X-Y-Z planes, there is a cell in which only activating the 3 planes can cause the desired change or read the desired state, by some physical effect that happens only when all the 3 planes are activated nor or at the cell.
c. At each such cell there is a 3-legged AND gate which allows connecting to the cell only if all the 3 planes intersect at that cell.
d. A combination of 3 independent moveable nano elements is used in each cell so that only moving the whole 3 creates an alignment that enables for example changing or reading the cell.
e. The vertical connections that connect each X line to its X plane and each Y line to its Y plane are at the edges of the horizontal layers, so no vertical connections have to be built inside the 3d cube.

4. The system of claim 2 wherein the data is stored in each cell by at least one of:
a. Moving at least one nano-scale object to at least 2 chooseable positions.
b. Changing the shape of at least one nano-scale object in at least 2 chooseable states.
c. Chemical change in at least 2 chooseable states.
d. Electrical change in at least 2 chooseable states.
e. Magnetic change in at least 2 chooseable states.

5. The system of claim 1 wherein the external connectors are comprised of flat shapes on at least one surface of the dimensional memory array and the memory device is kept in place by at least one of:
a. A moving element that can close on it when it is in the matching socket.
b. Small protrusions and/or sockets in various places
c. At least some of said shapes are at least a little sunk into the surface or at least a little protruding, in one or more of the planes, to make sure the cube sits in place.

6. A Random Access Memory (RAM) system for data storage and retrieval based on at least some nano-scale elements, wherein the cells and wires are created by lithography but each cell contains at least a number of nano-scale elements that enable the cell to reliably contain more than 2 values, so that more data can be kept in the same physical space.

7. The system of claim 6 wherein said nano-scale elements are a group of Bucky balls within the memory cell and the non-binary value stored in the cell is based on statistical attributes of the group of Bucky balls.

8. The system of claim 7 wherein the data values in said Bucky balls are changed by at least one of:
a. Adding and removing elements to them.
b. Making chemical changes them.
c. Changing their electrical charges.
d. changing their magnetic charges.

9. A 3-Dimensional Random Access Memory (RAM) method for data storage and retrieval, based on the steps of:
Using a large number of memory cells, each located at the crossing of at least two wires;
Using control circuits for accessing said cells;
Using external connectors for interface with other devices.

10. The method of claim 9 wherein at least one of the following features exist:
a. Said cells are nano-cells and at least the wires closest to the cells are nano-scale in terms of their thickness and distances from each other.
b. Said cells are normal RAM cells or MRAM (Magnetic RAM cells) but in a multi-layer structure.
c. Between at least some of the layers a heat conducting layer is used.
d. Between at least some of the layers a conducting layer is used which is grounded or carries a small constant DC current.
e. Each time a large number of cells is automatically accessed at the same time in order to increase the efficiency and/or even an entire layer in the 3d matrix can be read or written automatically by a single access.
f. Said cells and wires are in multiple layers of 2-dimensional arrays and at least 2 decoders are used in each layer for accessing the cells and there is at least one decoder or multiplexor for choosing the layer.
g. Said cells and wires are in a 3-dimensional array and at least 3 planes of activation are used to access each cell: an X plane, a Y plane, and a Z plane, so that the intersection of these planes defines the desired cell.

11. The method of claim 10 wherein said cells and wires are in a 3-dimensional array and at least one of the following features exist:
a. Said planes are defined so that Each X line is electrically connected to the corresponding X lines in the layers above and below it in the 3^{rd} dimension Z, Each Y line is electrically connected to the corresponding Y lines in the layers above and below it in the 3^{rd} dimension Z, and each Z line is connected to at least one of independent Y lines and independent X lines in the corresponding Z layer, thus creating said Z plane.
b. At each crossing point of the X-Y-Z planes, there is a cell in which only activating the 3 planes can cause the desired change or read the desired state, by some physical effect that happens only when all the 3 planes are activated nor or at the cell.
c. At each such cell there is a 3-legged AND gate which allows connecting to the cell only if all the 3 planes intersect at that cell.
d. A combination of 3 independent moveable nano elements is used in each cell so that only moving the whole 3 creates an alignment that enables for example changing or reading the cell.
e. The vertical connections that connect each X line to its X plane and each Y line to its Y plane are at the edges of the horizontal layers, so no vertical connections have to be built inside the 3d cube.

12. The method of claim 10 wherein the data is stored in each cell by at least one of:
a. Moving at least one nano-scale object to at least 2 chooseable positions.
b. Changing the shape of at least one nano-scale object in at least 2 chooseable states.
c. Chemical change in at least 2 chooseable states.
d. Electrical change in at least 2 chooseable states.
e. Magnetic change in at least 2 chooseable states.

13. The method of claim 9 wherein the external connectors are comprised of flat shapes on at least one surface of the 3-dimensional memory array and the memory device is kept in place by at least one of:
a. A moving element that can close on it when it is in the matching socket.
b. Small protrusions and/or sockets in various places
c. At least some of said shapes are at least a little sunk into the surface or at least a little protruding, in one or more of the planes, to make sure the cube sits in place.

14. A Random Access Memory (RAM) method for data storage and retrieval based on at least some nano-scale elements, wherein the cells and wires are created by lithography but each cell contains at least a number of nano-scale elements that enable the cell to reliably contain more than 2 values, so that more data can be kept in the same physical space.

15. The method of claim 14 wherein said nano-scale elements are a group of Bucky balls within the memory cell and the non-binary value stored in the cell is based on statistical attributes of the group of Bucky balls.

16. The method of claim 15 wherein the data values in said Bucky balls are changed by at least one of:
a. Adding and removing elements to them.
b. Making chemical changes them.
c. Changing their electrical charges.
d. changing their magnetic charges.

17. The system of claim 6 wherein said cells and said wires are created by lithography but each cell contains at least one of:
a. At least one smaller nano-RAM matrix, internally accessible thorough its own logic, and the cell can tell the inner matrix which inner cells to access, and said inner nano-matrix is at least one of 2-dimensional and 3-dimensional.
b. At least one inner 2-d or 3-d nano-chip that can itself address a large number of inner elements.

18. The method of claim 14 wherein said cells and said wires are created by lithography but each cell contains at least one of:
a. At least one smaller nano-RAM matrix, internally accessible thorough its own logic, and the cell can tell the inner matrix which inner cells to access, and said inner nano-matrix is at least one of 2-dimensional and 3-dimensional.
b. At least one inner 2-d or 3-d nano-chip that can itself address a large number of inner elements.

19. The system of claim 17 wherein at least one of the following exists:
a. Said inner nano-chip or inner matrix is contacted by giving it the serial number or the coordinates of at least one inner memory cell.
b. Said inner nano-chip or inner matrix behaves as a single cell that can have a very large number of values.
c. Multiple layers of such hybrid memory are stacked upon each other, so that in each layer each normally accessed cell is coupled to one or more nano-chips, and thus the 3rd dimension is also used on the macro level.

20. The method of claim 18 wherein at least one of the following exists:
a. Said inner nano-chip or inner matrix is contacted by giving it the serial number or the coordinates of at least one inner memory cell.
b. Said inner nano-chip or inner matrix behaves as a single cell that can have a very large number of values.
c. Multiple layers of such hybrid memory are stacked upon each other, so that in each layer each normally accessed cell is coupled to one or more nano-chips, and thus the 3^{rd} dimension is also used on the macro level.

21. A method for interfacing with a 3-Dimensional chip wherein external connectors are comprised of flat shapes on at least one surface of said 3-dimensional chip is kept in place by at least one of:
a. A moving element that can close on it when it is in the matching socket.
b. Small protrusions and/or sockets in various places
c. At least some of said shapes are at least a little sunk into the surface or at least a little protruding, in one or more of the planes, to make sure the cube sits in place.

22. The method of claim 21 wherein at least one of the following exists:
a. Said chip is a memory chip.
b. Most of the a logic required for running the memory is in the chip itself, so that on the outside there are much less connectors than would be required if the internal memory cells were accessed directly from the outside.

23. A 3-d magnetic nano-RAM wherein at least 3 planes of elongated laser beams are used to access the cells.
